(19) United States
(12) Patent Application Publication
(10) Pub. No.: US 2010/0133622 A1
(43) Pub. Date: Jun. 3, 2010

(54) Semiconductor device including MOSFET with controlled threshold voltage, and manufacturing method of the same

(75) Inventors: Toshiyuki Iwamoto, Kanagawa (JP); Kiyota Imai, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/591,545

(22) Filed: Nov. 23, 2009

(30) Foreign Application Priority Data
Nov. 28, 2008 (JP) 305672/2008

(51) Int. Cl. H01L 27/092; H01L 21/8238

(52) U.S. Cl. 257/369; 438/591; 438/216; 257/E21.632; 257/E27.062

(57) ABSTRACT

Provided is a semiconductor device including an N-MOSFET and a P-MOSFET on a semiconductor substrate. The N-MOSFET is formed on the semiconductor substrate, and includes a first gate insulating film including a first high-dielectric-constant film having a higher dielectric constant than a silicon oxide film. The P-MOSFET is formed on the semiconductor substrate, and includes a second gate insulating film including a second high-dielectric-constant film having a higher dielectric constant than a silicon oxide film. The first high-dielectric-constant film contains a first metal, and a concentration of the first metal increases from a surface of the first high-dielectric-constant film toward the semiconductor substrate. The second high-dielectric-constant film contains a second metal, and a concentration of the second metal decreases from a surface of the second high-dielectric-constant film toward the semiconductor substrate.

### BACKGROUND OF THE INVENTION

1. Field of the Invention

The present invention relates to a semiconductor device including as a gate insulating film a high-dielectric-constant film having a higher dielectric constant than silicon oxide, and to a manufacturing method of the semiconductor device.

2. Description of the Related Art

In recent years, as miniaturization of LSI has been advanced, deterioration of a driving current and a gate leakage current have emerged as problems. The deterioration is caused by depletion in a polysilicon gate electrode constituting each metal-oxide semiconductor field effect transistor (MOSFET), and the gate leakage current is generated as a result of thinning of a gate insulating film. To address these problems, there have been studied: a technique of avoiding depletion in the electrode by using a metal gate electrode; and a technique of reducing a gate leakage current by increasing a physical film thickness of a gate insulating film with a high-dielectric-constant film (high-k film) being used as the gate insulating film.

In an MOSFET using a high-k insulating film and a metal gate electrode, reduction of a threshold voltage is required. A Dual-High-k technology has been proposed as a technology for the threshold voltage reduction.

The Dual-High-k technology is a technology in which: films containing threshold-voltage controlling metals, which are suitable for an N-channel MOSFET (hereinafter, referred to as NMOSFET) and for a P-channel MOSFET (hereinafter, referred to as PMOSFET), respectively, are formed on a High-k insulating film; and thereafter, the threshold-voltage-controlling metals are diffused in an interface between a SiO₂ film and the high-dielectric-constant film through heat treatment. The threshold voltage reduction can be achieved by having the threshold-voltage-controlling metals in the interface between the SiO₂ film and the high-dielectric-constant film.

A conventional semiconductor device manufacturing method employing the Dual-High-k technology will be described below with reference to FIGS. 12A to 13C. First of all, an element isolation region 104 (Shallow Trench Isolation: STI) is formed on a semiconductor substrate 102. Next, a thermally oxidized film 106 is formed on the semiconductor substrate 102, and a HfO₂ film 108 is formed thereon as a high-dielectric-constant film. Subsequently, a La film 110, which is a threshold-voltage-controlling metal for an NMOSFET, is formed on the HfO₂ film 108 (FIG. 12A).

Next, as shown in FIG. 12B, an NMOSFET formation region 200 is masked with a resist 112. Thereafter, the La film 110 in a PMOSFET formation region 210 is removed (FIG. 12C) through etching. Subsequently, the resist 112 is removed (FIG. 13A).

Then, an Al₂O₃ film 114, which is a threshold-voltage-controlling metal for a PMOSFET, is formed on an entire surface (FIG. 13B), and the PMOSFET formation region 210 is masked with a resist 116 (FIG. 13C). Thereafter, the Al₂O₃ film 114 in the NMOSFET formation region 200 is removed through etching. Subsequently, the resist 116 is removed.

After that, after metal gate electrodes, polysilicon electrodes and side walls are formed, impurities for source and drain diffusion layers are implanted. Furthermore, through application of heat treatment, the impurities in source and drain regions are activated and simultaneously the threshold-voltage-controlling metals are diffused from a surface of the high-dielectric-constant film toward an interface between the SiO₂ film and the high-dielectric-constant film. Thereby, a semiconductor device is obtained in which: La atoms exist in the interface between the SiO₂ film and the high-dielectric-constant film in the NMOSFET; and Al atoms exist in the interface between the SiO₂ film and the high-dielectric-constant film in the PMOSFET.

Note that a subtractive method of forming metal gate electrodes on the high-dielectric-constant film is disclosed in Japanese Patent Translation Publication No. 2008-507141 as a method of producing a CMOS device including plural metal gate electrodes.

Additionally, a technique of controlling a threshold voltage by providing an AlO film between a nickel silicide gate electrode of a PMOSFET and a HfSiON insulating film is disclosed in Japanese Patent Application Publication No. 2008-060538.

However, in the above manufacturing method, when the Al₂O₃ film in the NMOSFET formation region is removed by use of dilute hydrofluoric acid (DHF), the La film which is a layer under the Al₂O₃ film reacts with F in DHF, and turns into LaF₃. LaF₃ is a hardly-soluble foreign material, and is difficult to remove through wet processing or the like. As a result, threshold voltage control and the device are decreased in reliability.

The above problem arises also in a case using a La₂O₃ film instead of the La film, and in a case using an Al film instead of the Al₂O₃ film.

Thus, there has been a possibility of a foreign material being generated in a high-dielectric-constant film when an attempt is made so as to diffuse a first metal and a second metal in the high-dielectric-constant film in an NMOSFET and in the high-dielectric-constant film in a PMOSFET, respectively.

### SUMMARY OF THE INVENTION

The present invention provides a semiconductor device including an N-channel MOSFET and a P-channel MOSFET on a semiconductor substrate, wherein the N-channel MOSFET is formed on the semiconductor substrate, and includes a first gate insulating film including a first high-dielectric-constant film having a higher dielectric constant than a silicon oxide film, the P-channel MOSFET is formed on the semiconductor substrate, and includes a second gate insulating film including a second high-dielectric-constant film having a higher dielectric constant than a silicon oxide film, the first high-dielectric-constant film contains a first metal, and a concentration of the first metal increases from a surface of the first high-dielectric-constant film toward the semiconductor substrate, and the second high-dielectric-constant film contains a second metal, and a concentration of the second metal decreases from a surface of the second high-dielectric-constant film toward the semiconductor substrate.

The present invention provides a manufacturing method of a semiconductor device, which includes an N-channel MOSFET and a P-channel MOSFET on a semiconductor substrate, comprising: forming a film containing a first metal in an N-channel MOSFET forming region and a P-channel MOSFET formation region on the semiconductor substrate; removing the film containing the first metal, from the P-channel MOSFET formation region; forming a high-dielectric-constant film in the N-channel MOSFET forming region and the P-channel MOSFET formation region, the high-dielectric-constant film having a higher dielectric constant than a silicon oxide film; forming a film containing a second metal in the N-channel MOSFET forming region and the P-channel MOSFET formation region; removing the film containing the second metal, from the N-channel MOSFET formation region; and by applying heat treatment to the semiconductor substrate, forming a first high-dielectric-constant film through diffusion of the first metal in the high-dielectric-constant film, and also forming a second high-dielectric-constant film through diffusion of the second metal in the high-dielectric-constant film.

According to the present invention, the first metal, which is a threshold-value-controlling metal of the NMOSFET, is not exposed when the second metal, which is a threshold-value-controlling metal of the PMOSFET, is removed from the NMOSFET forming region. Accordingly, when the first metal and the second metal are diffused in the high-dielectric-constant film in the NMOSFET and in the high-dielectric-constant film in the PMOSFET, respectively, any foreign materials can be prevented from developing on the high-dielectric-constant films.

According to the present invention, when a first metal and a second metal are diffused in the high-dielectric-constant film in the NMOSFET and in the high-dielectric-constant film in the PMOSFET, respectively, any foreign material can be prevented from developing on a high-dielectric-constant film.

### BRIEF DESCRIPTION OF THE DRAWINGS

FIG. 1A is a cross-sectional view showing a configuration of a semiconductor device according to an embodiment.

FIGS. 1B and 1C are charts showing concentration profiles of threshold-value-controlling metals in gate insulating films of the semiconductor device according to the embodiment.

FIGS. 2A to 2D are cross-sectional views showing a manufacturing method of the semiconductor device shown in FIG. 1A.

FIGS. 3A to 3D are cross-sectional views showing the manufacturing method of the semiconductor device shown in FIG. 1A.

FIGS. 4A to 4D are cross-sectional views showing the manufacturing method of the semiconductor device shown in FIG. 1A.

FIGS. 5A to 5D are cross-sectional views showing the manufacturing method of the semiconductor device shown in FIG. 1A.

FIGS. 6A to 6D are cross-sectional views showing the manufacturing method of the semiconductor device shown in FIG. 1A.

FIGS. 7A to 7D are cross-sectional views showing the manufacturing method of the semiconductor device shown in FIG. 1A.

FIGS. 8A to 8D are cross-sectional views showing the manufacturing method of the semiconductor device shown in FIG. 1A.

FIGS. 9A to 9D are cross-sectional views showing the manufacturing method of the semiconductor device shown in FIG. 1A.

FIGS. 10A to 10D are cross-sectional views showing the manufacturing method of the semiconductor device shown in FIG. 1A.

FIGS. 11A to 11C are cross-sectional views showing the manufacturing method of the semiconductor device shown in FIG. 1A.

FIGS. 12A to 12C are cross-sectional views showing a conventional manufacturing method of a semiconductor device.

FIGS. 13A to 13C are cross-sectional views showing the conventional manufacturing method of the semiconductor device.

### DESCRIPTION OF THE PREFERRED EMBODIMENT

An embodiment of the present invention will be described below with reference to the drawings. Note that like reference numerals are used for like constituent elements throughout the drawings, so that description will be omitted as appropriate.

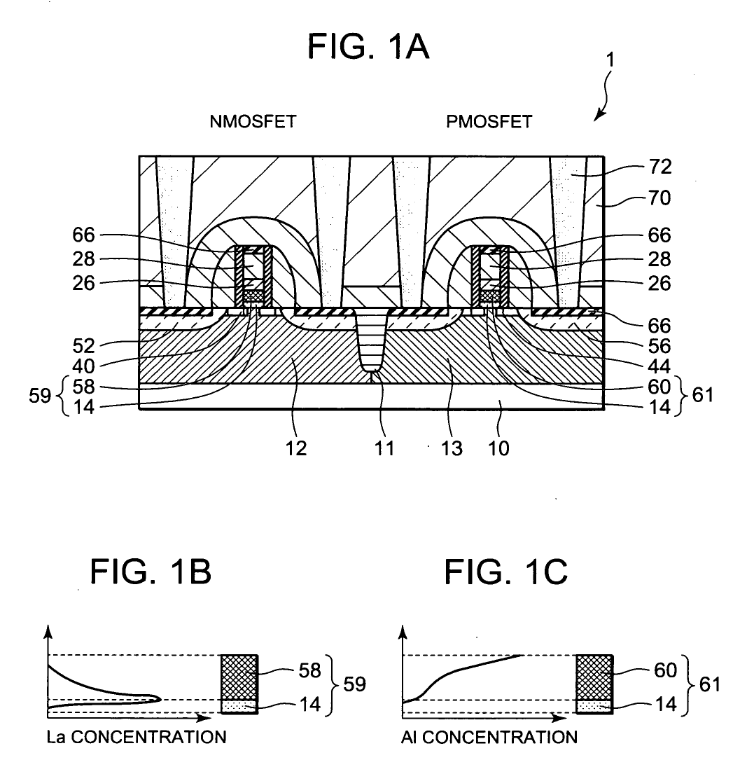

FIG. 1A is a cross-sectional view showing a configuration of a semiconductor device 1 in this embodiment. This semiconductor device 1 includes an NMOSFET and a PMOSFET on a semiconductor substrate 10. A gate insulating film 59 (a first insulating film) of the NMOSFET includes a high-dielectric-constant film 58 (a first high-dielectric-constant film) having a higher dielectric constant than a silicon oxide film. A gate insulating film 61 (a second insulating film) of the PMOSFET includes a high-dielectric-constant film 60 (a second high-dielectric-constant film). Note that the NMOSFET and the PMOSFET include silicon oxide films 14 formed between the semiconductor substrate 10 and the high-dielectric-constant film 58, and between the semiconductor substrate 10 and the high-dielectric-constant film 60, respectively. That is, while the gate insulating film 59 is formed of a film in which the silicon oxide film 14 and the high-dielectric-constant film 58 are laminated, the gate insulating film 61 is formed of a film in which the silicon oxide film 14 and the high-dielectric-constant film 60 are laminated. Note that any one of a silicon oxide nitride film and a silicon nitride film may be used in place of each of the silicon oxide films 14, or a film in which plural films selected from a silicon oxide film, a silicon oxide nitride film and a silicon nitride film are laminated may be used in place thereof.

The high-dielectric-constant film 58 is formed of, for example, any one of HfO₂ and ZrO₂, and contains La (a first metal) which is a threshold-voltage-controlling metal of the NMOSFET. As shown in FIG. 1B, the concentration of La in the high-dielectric-constant film 58 increases from a surface of the high-dielectric-constant film 58 toward the semiconductor substrate 10. Other than La, for example, Dy may be used as the threshold-voltage-controlling metal of the NMOSFET. Use of Dy also has the same effect as use of La with respect to threshold voltage control for the NMOSFET.

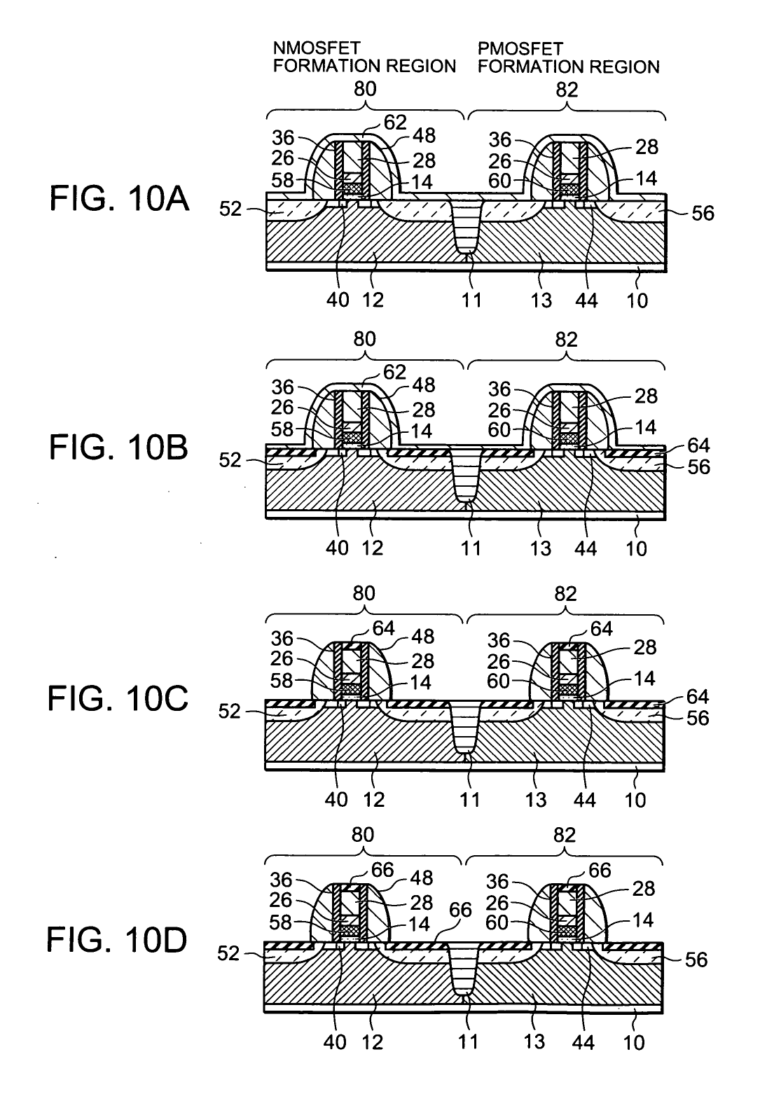

The high-dielectric-constant film 60 is, for example, formed of any one of HfO₂ and ZrO₂, and contains Al (a second metal) which is a threshold-voltage-controlling metal of the PMOSFET. As shown in FIG. 10, the concentration of Al in the high-dielectric-constant film 60 decreases from a surface of the high-dielectric-constant film 60 toward the semiconductor substrate 10.

The NMOSFET and the PMOSFET have metal gate electrodes 26 located on the gate insulating film 59 and on the gate insulating film 61, respectively. Each of the metal gate electrodes 26 is formed of at least one metal selected from a group consisting of TiN, WN, TaSiN, TiAlN, Ti, W, TiAl and Ru.

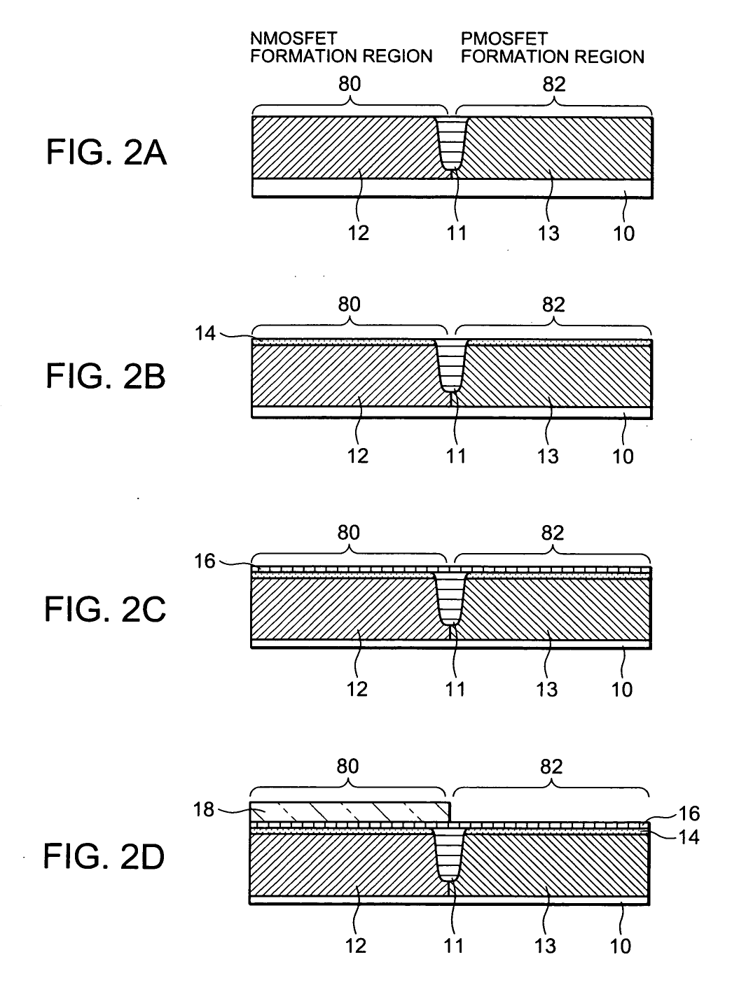

Next, a manufacturing method of the semiconductor device according to the embodiment of the present invention will be described with reference to cross-sectional views shown in FIGS. 2A to 11C.

First of all, as shown in FIG. 2A, an element isolation oxide film (an element-isolating insulating film) 11 is formed on the semiconductor substrate 10 through STI (Shallow Trench Isolation), for example. Thereafter, a P well 12 and an N well 13 are formed in an NMOSFET formation region 80 and in a PMOSFET formation region 82, respectively. Then, the silicon oxide films 14 each having a thickness of 1.0 nm are formed as base-gate insulating films (FIG. 2B). A formation method of the silicon oxide films 14 may be a chemical solution processing method using a mixture of sulfuric acid and hydrogen peroxide solution or ozonized water, a thermal oxidization method, or the like.

Thereafter, as shown in FIG. 2C, a La film 16 is formed on the silicon oxide films 14 through sputtering. The La film 16 is formed in both of the NMOSFET formation region 80 and the PMOSFET formation region 82. A film thickness of the La film 16 is, for example, in the range not less than 0.1 nm and not more than 5 nm. Any one of a Dy film, a La₂O₃ film and a Dy₂O₃ film may be used in place of the La film.

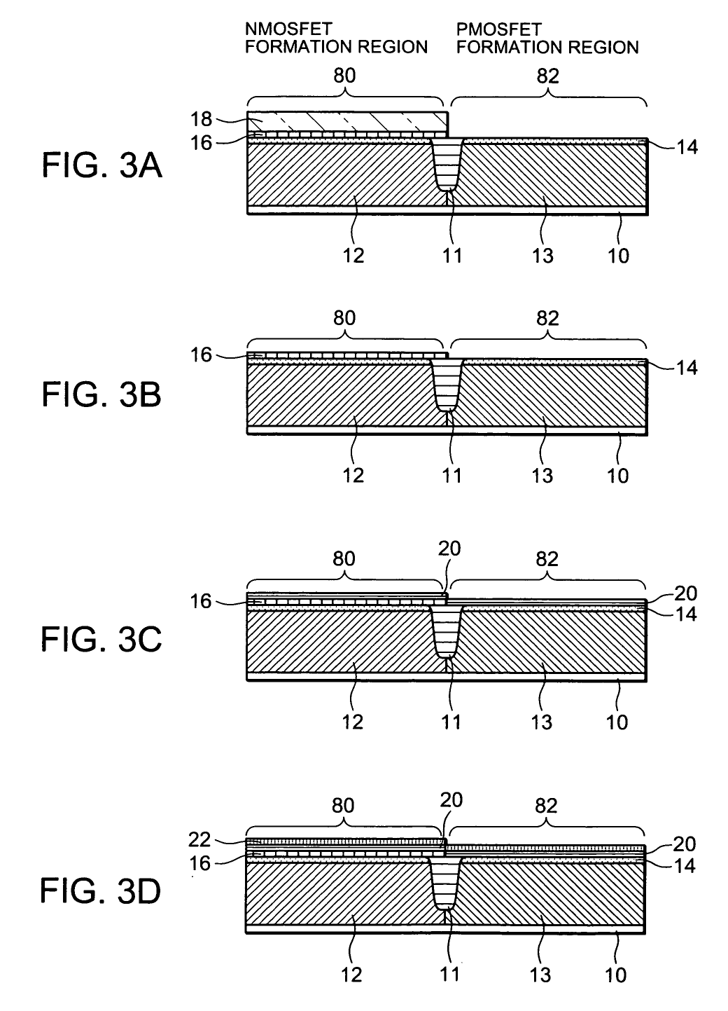

Then, as shown in FIG. 2D, a resist film 18 is formed. The resist film 18 is formed in the NMOSFET formation region 80, and is excluded from the PMOSFET formation region 82. Subsequently, as shown in FIG. 3A, the La film in the PMOSFET formation region 82 is removed through a wet-etching process with the resist film 18 serving as a mask. The wet-etching process can be applied, for example, by use of HCl/H₂O (dilute hydrochloric acid). However, anyone of H₂O, H₂O₂/H₂O and O₃/H₂O may be used in place of HCl/H₂O (dilute hydrochloric acid).

Next, the resist film 18 is removed through an ashing process (FIG. 3B).

Thereafter, as shown in FIG. 3C, a High-k insulating film (high-dielectric-constant film) 20 is formed. The High-k insulating film 20 is, for example, a HfO₂ film. However, a ZrO₂ film may be used in place of the HfO₂ film. A film formation method of the High-k insulating film 20 is, for example, ALCVD (Atomic Layer Chemical Vapor Deposition). A film thickness of the High-k insulating film 20 is, for example, 1.0 to 5.0 nm.

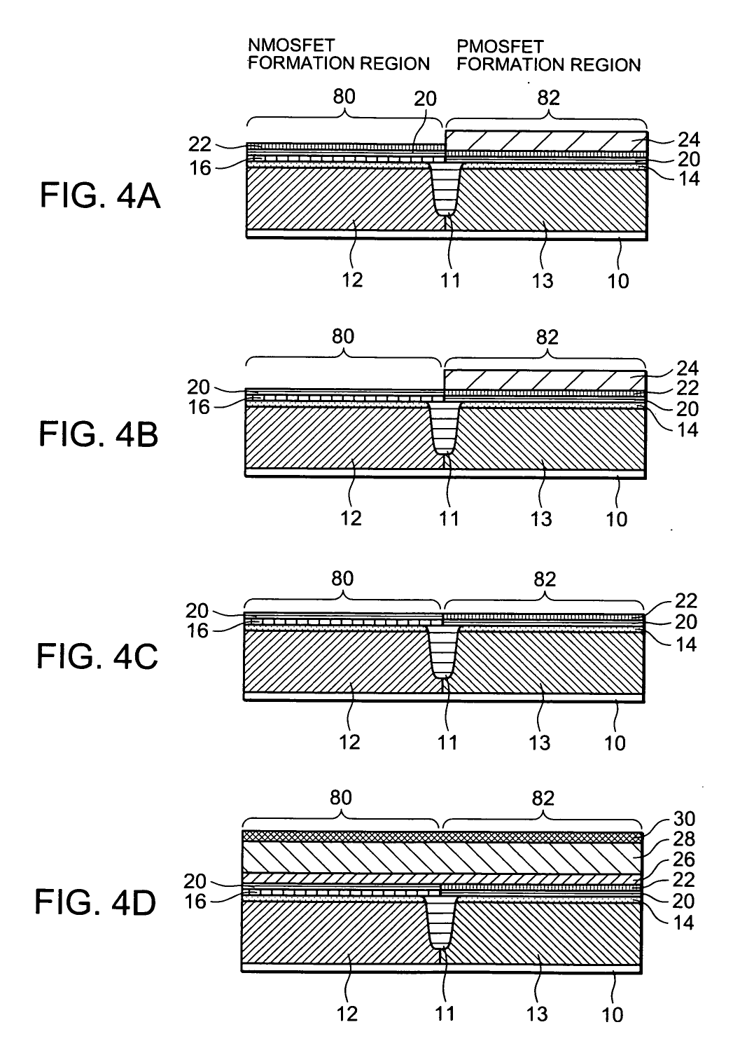

Next, an Al₂O₃ film 22 is formed as shown in FIG. 3D. A film formation method thereof is a method selected from sputtering, ALCVD and CVD. A film thickness thereof is in the range not less than 0.1 nm and not more than 5.0 nm. Additionally, an Al film may be used in place of the Al₂O₃ film 22. Then, as shown in FIG. 4A, a resist film 24 is formed.

The resist film 24 is formed in the PMOSFET formation region 82, and is excluded from the NMOSFET formation region 80. Subsequently, the Al₂O₃ film 22 in the NMOSFET formation region 80 is removed through a wet-etching process with the resist film 24 serving as a mask (FIG. 4B). A dilute HF/H₂O₂ mixture is used for the wet-etching process. Since HfO₂ forming the High-k insulating film 20 can achieve a high selectivity ratio against the dilute HF/H₂O₂ mixture, the Al₂O₃ film 22 can be selectively removed. For example, any one of an HF/H₂O₂/H₂O mixture and a TMAH/H₂O mixture may be used other than the dilute HF/H₂O mixture as a chemical solution used in the wet-etching process.

After the removal of the Al₂O₃ film 22, the resist film 24 is removed through an ashing process (FIG. 4C). Thereafter, as shown in FIG. 4D, metal gate electrodes 26, silicon gate electrodes 28 and hard masks 30 are formed as films in that order. The silicon gate electrodes 28 are, for example, polysilicon electrodes, but may be formed otherwise as amorphous silicon electrodes.

Each of the metal gate electrodes 26 is formed of at least one metal selected from materials TiN, WN, TaSiN, TiAlN, Ti, W and Ru, and has a film thickness in the range not less than 1 nm and not more than 20 nm. A film formation method thereof is sputtering.

Additionally, each of the silicon gate electrodes 28 is formed through CVD or sputtering. A film thickness thereof is in the range not less than 20 nm and not more than 100 nm. A material of the hard masks 30 is SiO₂. A film formation method thereof is CVD. A film thickness thereof is in the range not less than 10 nm and not more than 50 nm.

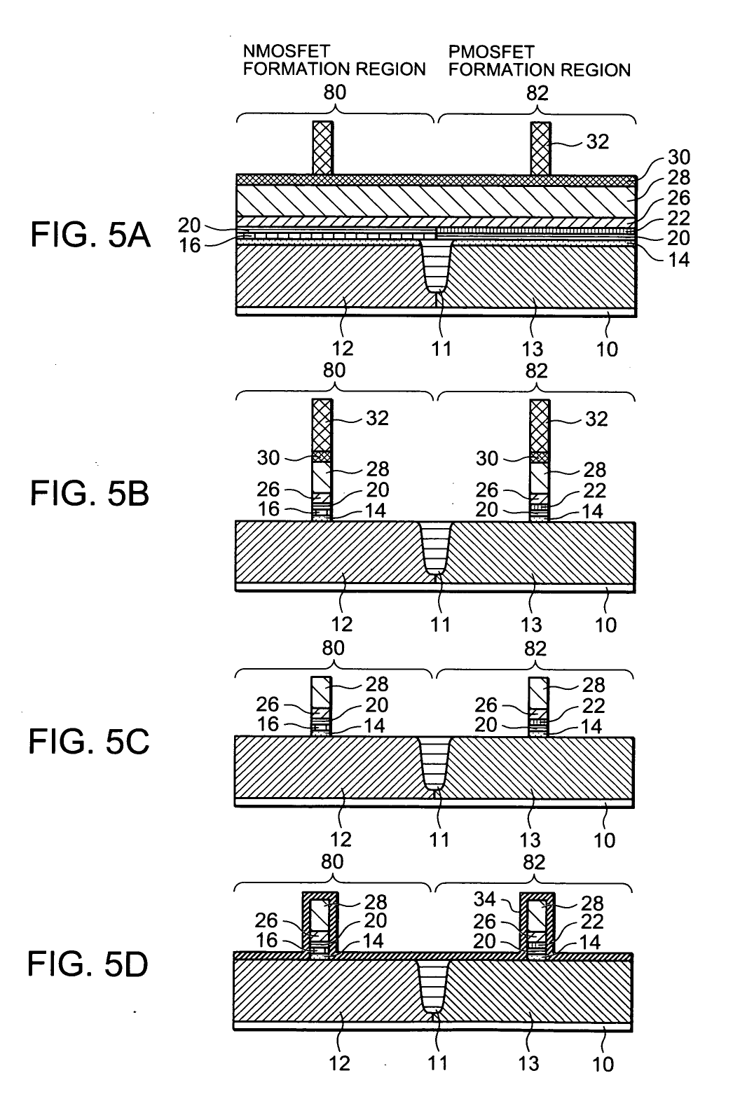

Then, as shown in FIG. 5A, a resist film 32 is formed. Subsequently, the metal gate electrodes 26, the silicon gate electrodes 28 and the hard masks 30 are processed through dry-etching with the resist film 32 serving as a mask (FIG. 5B). At that time, there are some cases where the silicon oxide films 14, the La film 16, the High-k film 20 and the Al₂O₃ film 22 also are processed. Thereafter, the resist film 32 and the hard masks 30 are removed, and, as shown in FIG. 5C, gate electrodes formed of the respective metal gate electrodes 26 and the respective silicon gate electrodes 28 are formed.

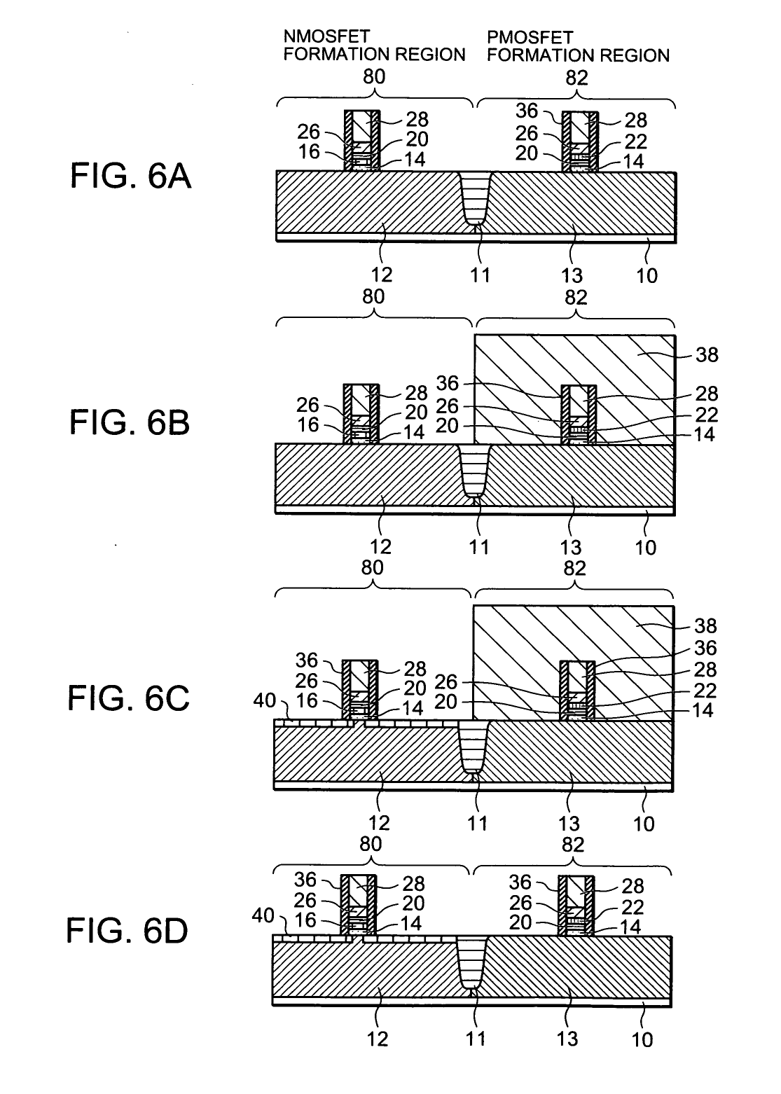

Then, a nitride film 34 is formed as shown in FIG. 5D, and offset spacer films 36 are formed through dry-etching as shown in FIG. 6A.

Thereafter, the PMOSFET formation region 82 is masked with a resist film 38 (FIG. 6B), and an Extension region 40 is formed in the NMOSFET formation region 80 through ion implantation (FIG. 6C). Impurities with which the NMOSFET formation region 80 is irradiated are, for example, As and BF₂. Implantation conditions are: an ion implantation energy of 2 keV, an ion irradiation density of 8E14 atoms/cm² and an ion implantation angle of 0 degrees when As is used as one of the impurities with which the irradiation is performed; and an ion implantation energy of 50 keV, an ion irradiation density of 3E13 atoms/cm² and an ion implantation angle of 30 degrees when BF₂ is used as one of the impurities. Thereafter, the resist film 38 is removed (FIG. 6D).

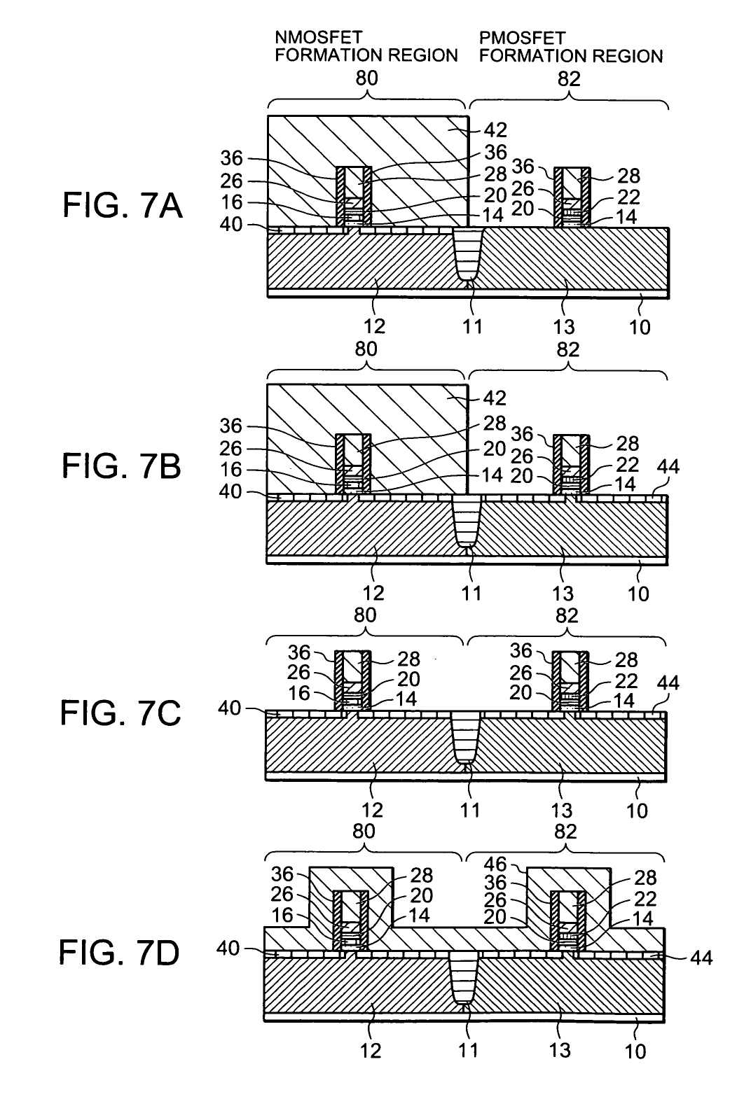

Subsequently, the NMOSFET formation region 80 is masked with a resist film 42 (FIG. 7A), and an Extension region 44 is formed in the PMOSFET formation region 82 through ion implantation (FIG. 7B). Impurities with which the NMOSFET formation region 80 is irradiated are, for example, BF₂ and As. Implantation conditions are: an ion implantation energy of 3 keV, an ion irradiation density of 8E14 atoms/cm² and an ion implantation angle of 0 degrees when BF₂ is used as one of the impurities; and, an ion implantation energy of 50 keV, an ion irradiation density of 3E13 atoms/cm² and an ion implantation angle of 30 degrees when As is used as one of the impurities with which the irradiation is performed.

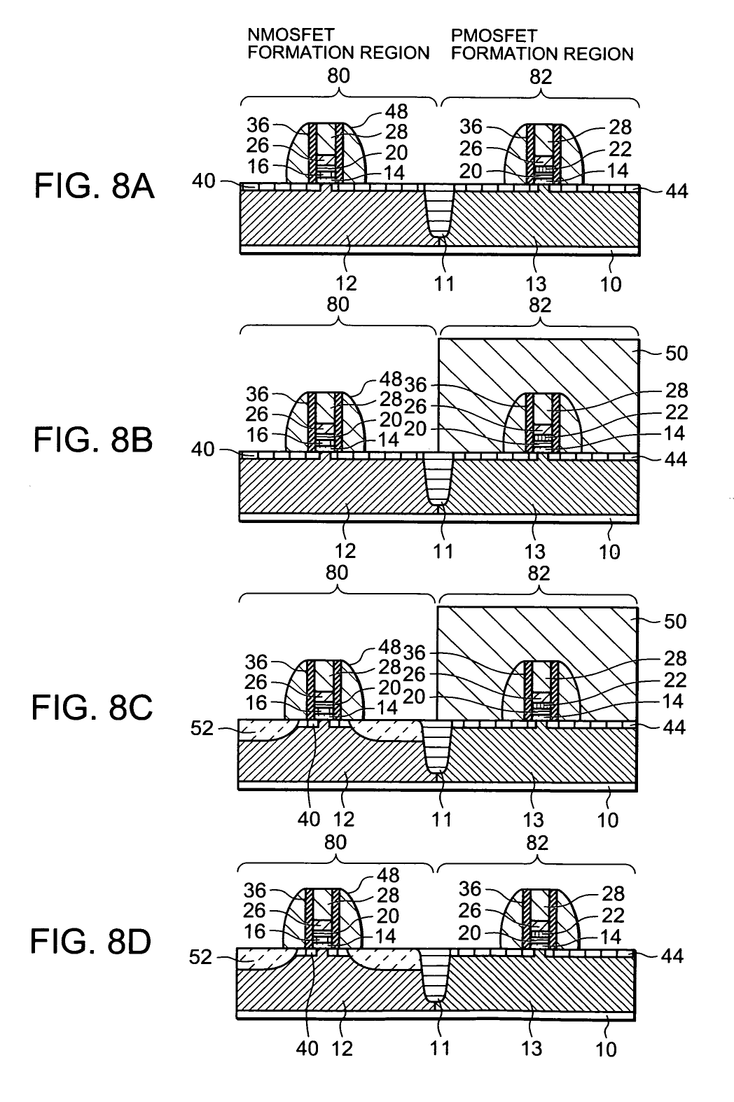

Then, after the resist film 42 is removed (FIG. 7C), a sidewall spacer film 46 formed of any one of a nitride film and an oxide film is formed (FIG. 7D), and sidewall spacer films 48 are formed as shown in FIG. 8A with application of dry-etching to the sidewall spacer film 46.

Thereafter, the PMOSFET formation region 82 is masked with a resist film 50 (FIG. 8B), and a Deep SD region 52 is formed in the NMOSFET formation region 80 through ion implantation (FIG. 8C). Impurities with which the NMOSFET formation region 80 is irradiated are, for example, As and P. Implantation conditions are: an ion implantation energy of 20 keV, an ion irradiation density of 2E15 atoms/cm² and an ion implantation angle of 0 degrees when As is used as one of the impurities with which the irradiation is performed; and an ion implantation energy of 20 keV, an ion irradiation density of 5E13 atoms/cm² and an ion implantation angle of 0 degrees when the P is used as one of the impurities. Thereafter, the resist film 50 is removed (FIG. 8D).

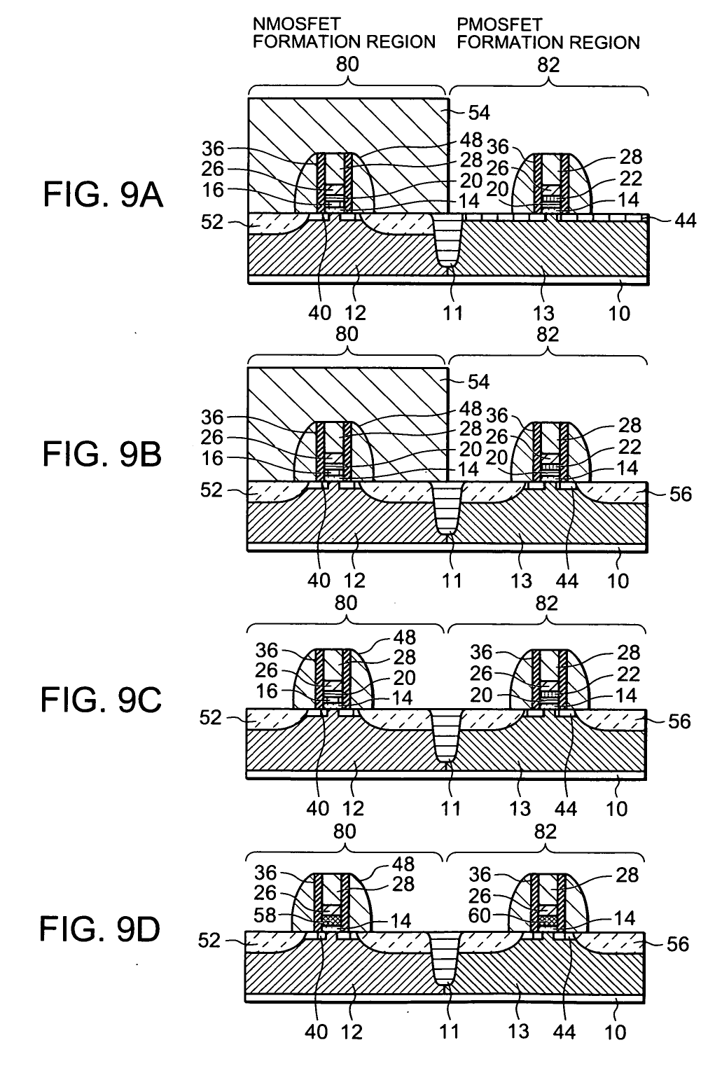

Subsequently, the NMOSFET formation region 80 is masked with a resist film 54 (FIG. 9A), and a Deep SD region 56 is formed in the PMOSFET formation region 82 through ion implantation (FIG. 9B). An impurity with which the PMOSFET formation region 82 is irradiated is, for example, B, and the Deep SD region 52 is formed through implantation of B performed in two times. Conditions in one of the two times when the implantation of B is performed are: an ion implantation energy of 1.5 keV, an ion irradiation density of 1.5E15 atoms/cm² and an ion implantation angle of 0 degrees. Conditions for in the other of the two times when the implantation of B is performed are: an ion implantation energy of 3.5 keV, an ion irradiation density of 5E13 atoms/cm² and an ion implantation angle of 0 degrees. Thereafter, the resist film 54 is removed (FIG. 9C).

Then, the impurities in the Extension regions 40 and 44, and the Deep SD regions 52 and 56 are activated with application of heat treatment (FIG. 9D). A heat treatment condition is, for example, not less than 800 degrees centigrade and not more than 1350 degrees centigrade, and a heat treatment period is not less than 1 millisecond and not more than 1 second. Through this heat treatment, the ion-implanted impurities are activated. Additionally, in the NMOSFET formation region 80, La diffuses in the high-dielectric-constant film, whereby the high-dielectric-constant film 58, which is a La-containing HfO₂ film, is formed. On the other hand, in the PMOSFET formation region 82, Al diffuses in the high-dielectric-constant film, whereby the high-dielectric-constant film 60, which is an Al-containing HfO₂ film, is formed.

As a result, in the high-dielectric-constant film 58, the La concentration has a distribution in which the La concentration increases from the surface of the high-dielectric-constant film 58 toward the semiconductor substrate 10, as shown in FIG. 1B.

In contrast, in the high-dielectric-constant film 60, the Al concentration has a distribution in which the Al concentration decreases from the surface of the high-dielectric-constant film 60 toward the semiconductor substrate 10, as shown in FIG. 10. Thereafter, as shown in FIG. 10A, a Ni/Pt alloy film 62 is formed through sputtering so as to have a film thickness of about 8 nm. A Pt content in the Ni/Pt alloy film 62 is about 5%. Subsequently, primary silicide layers 64 are formed, for example, with application of heat treatment at 375 degrees centigrade thereto (FIG. 10B). Then, unreacted portions of the Ni/Pt alloy film 62 are removed by use of aqua regia, whereby a surface of the primary silicide layer 64 is exposed (FIG. 100). Next, secondary silicide layers 66 are formed with application of heat treatment at 550 degrees centigrade thereto (FIG. 10D).

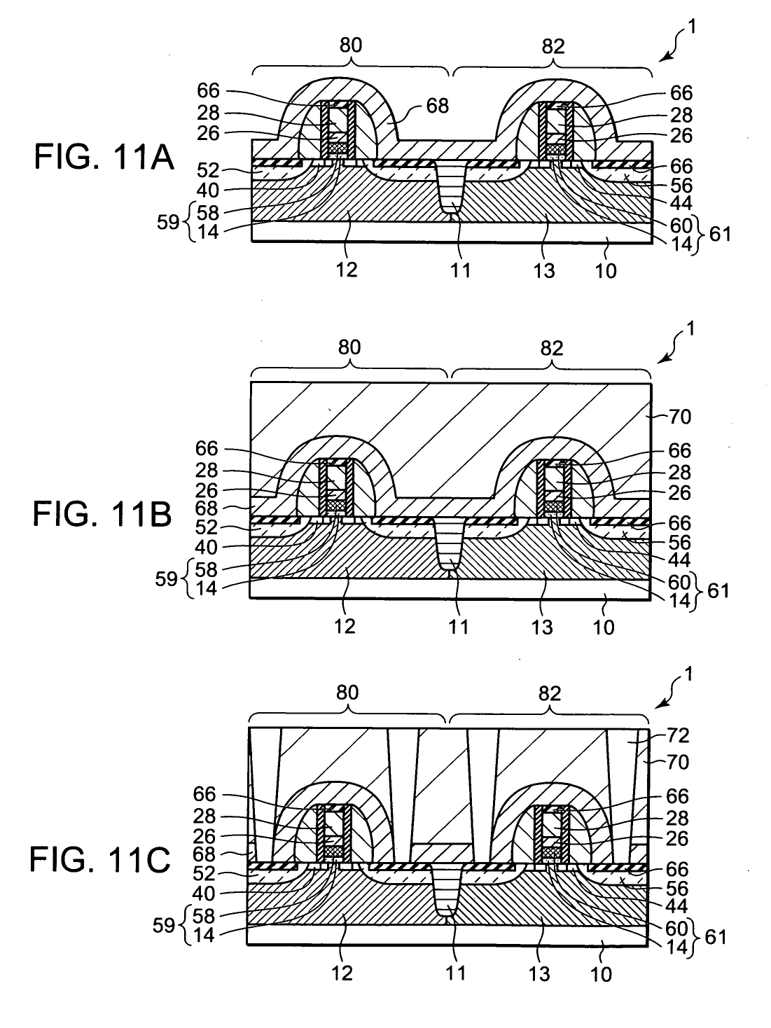

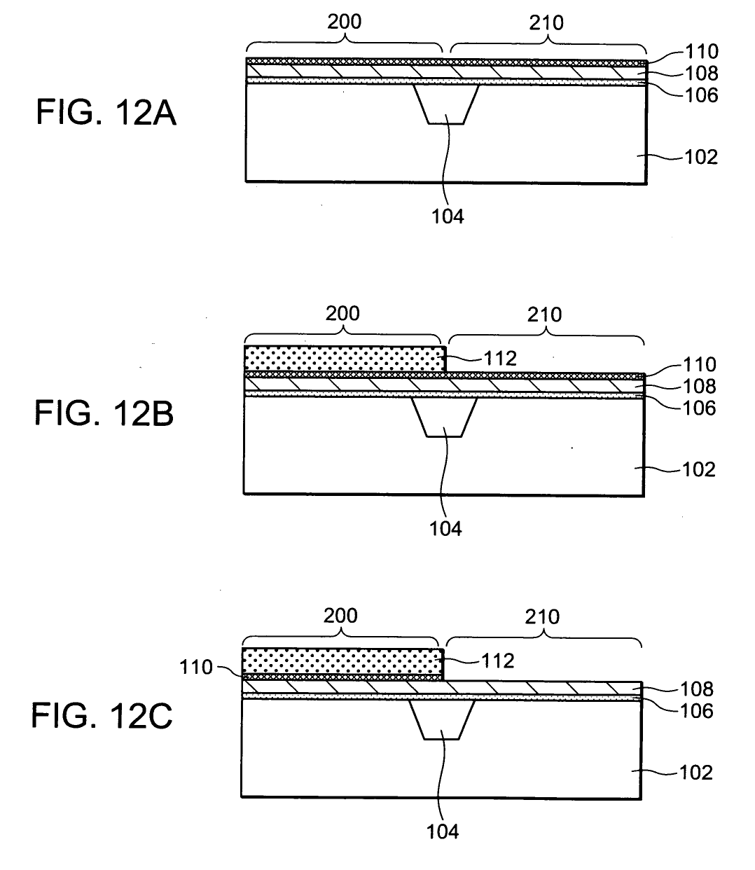

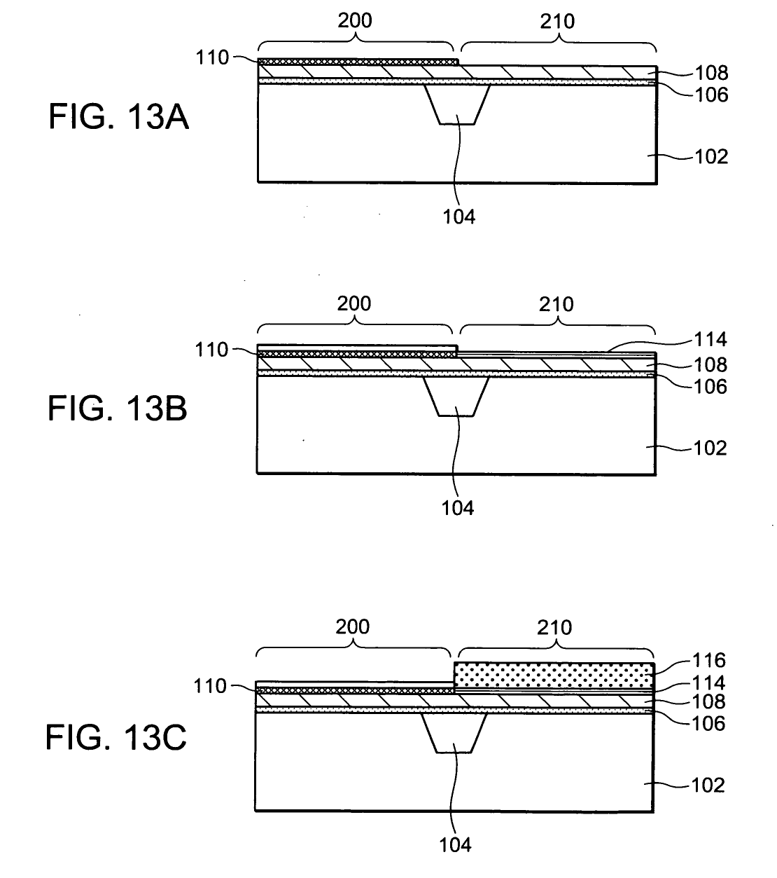

Then, as shown in FIG. 11A, a contact-etching stopper film 68 is formed. As a material for the contact-etching stopper film 68, for example, a nitride film may be used. A film thickness thereof is not less than 10 nm and not more than 100 nm. Furthermore, an interlayer dielectric film 70 formed of an oxide film is formed (FIG. 11B), and contacts 72 are formed in the interlayer dielectric film 70 (FIG. 11C). Thereby, the semiconductor device 1 shown in FIGS. 1A to 1C is obtained.

Next, advantageous effects of this embodiment will be described.

As shown in FIG. 4A, the Al₂O₃ film exposed on a surface of the NMOSFET formation region 80 is removed with application of a wet-etching process thereto. As shown in FIG. 4B, the La film 16 is not exposed on a surface obtained after the removal of the Al₂O₃ film while the High-k film 20 is exposed thereon. The La film 16 is therefore not exposed to an etching solution. Accordingly, no foreign material such as LaF₃ is formed. Consequently, La can be uniformly diffused in the High-k film 20 through the heat treatment applied thereafter, whereby a threshold voltage of the NMOSFET can be sufficiently controlled. Accordingly, a high-performance and highly reliable semiconductor device can be obtained.

Furthermore, in the semiconductor device according to this embodiment, the La concentration is distributed in the high-dielectric-constant film 58 in such a manner as to increase from the surface of the high-dielectric-constant film 58 toward the semiconductor substrate 10. In contrast, the Al concentration is distributed in the high-dielectric-constant film 60 in such a manner as to decrease from the surface of the high-dielectric-constant film 60 toward the semiconductor substrate 10. Additionally, both of La and Al₂O₃ can be prevented from remaining in the PMOSFET and in the NMOSFET, respectively. Accordingly, the threshold values of both of the NMOSFET and the PMOSFET can be accurately controlled.

Although the embodiment of the present invention has been described above with reference to the drawings, these are exemplification of the present invention, and various configurations other than the abovementioned one may alternatively be employed.

What is claimed is:

1. A semiconductor device comprising an N-channel MOSFET and a P-channel MOSFET on a semiconductor substrate, wherein
the N-channel MOSFET is formed on the semiconductor substrate, and includes a first gate insulating film including a first high-dielectric-constant film having a higher dielectric constant than a silicon oxide film,
the P-channel MOSFET is formed on the semiconductor substrate, and includes a second gate insulating film including a second high-dielectric-constant film having a higher dielectric constant than a silicon oxide film,
the first high-dielectric-constant film contains a first metal, and a concentration of the first metal increases from a surface of the first high-dielectric-constant film toward the semiconductor substrate, and
the second high-dielectric-constant film contains a second metal, and a concentration of the second metal decreases from a surface of the second high-dielectric-constant film toward the semiconductor substrate.

2. The semiconductor device according to claim 1, wherein
the first gate insulating film is formed of a laminated film including the first high-dielectric-constant film and at least one film which is formed between the semiconductor substrate and the first high-dielectric-constant film and which is selected from the group consisting of a silicon oxide film, a silicon oxide-nitride film and a silicon nitride film, and
the second gate insulating film is formed of a laminated film including the second high-dielectric-constant film and at least one film which is formed between the semiconductor substrate and the second high-dielectric-constant film, and which is selected from the group consisting of a silicon oxide film, a silicon oxide-nitride film and a silicon nitride film.

3. The semiconductor device according to claim 1, wherein each of the first and second gate insulating films is formed of any one of HfO₂ and ZrO₂.

4. The semiconductor device according to claim 1, wherein the first metal is any one of La and Dy.

5. The semiconductor device according to claim 1, wherein the second metal is Al.

6. The semiconductor device according to claim 1, further comprising gate electrodes on the respective first and second high-dielectric-constant films, the gate electrodes each being formed of a third metal.

7. The semiconductor device according to claim 6, wherein the third metal contains at least one metal selected from the group consisting of TiN, WN, TaSiN, TiAlN, Ti, W, TiAl and Ru.

8. A manufacturing method of a semiconductor device, which includes an N-channel MOSFET and a P-channel MOSFET on a semiconductor substrate, comprising:
forming a film containing a first metal in an N-channel MOSFET forming region and a P-channel MOSFET formation region on the semiconductor substrate;
removing the film containing the first metal, from the P-channel MOSFET formation region;
forming a high-dielectric-constant film in the N-channel MOSFET forming region and the P-channel MOSFET formation region, the high-dielectric-constant film having a higher dielectric constant than a silicon oxide film;
forming a film containing a second metal in the N-channel MOSFET forming region and the P-channel MOSFET formation region;
removing the film containing the second metal, from the N-channel MOSFET formation region; and
by applying heat treatment to the semiconductor substrate, forming a first high-dielectric-constant film through diffusion of the first metal in the high-dielectric-constant film, and also forming a second high-dielectric-constant film through diffusion of the second metal in the high-dielectric-constant film.

9. The manufacturing method of a semiconductor device according to claim 8, further comprising:
before forming the film containing the first metal, forming at least one film in the N-channel MOSFET forming region and the P-channel MOSFET formation region on the semiconductor substrate, the at least one film being selected from the group consisting of a silicon oxide film, a silicon oxide-nitride film and a silicon nitride film.

10. The manufacturing method of a semiconductor device according to claim 8, wherein the high-dielectric-constant film is formed of any one of HfO₂ and ZrO₂.

11. The manufacturing method of a semiconductor device according to claim 8, wherein the film containing the first metal is formed of at least any one selected from the group consisting of a La film, a Dy film, a La₂O₃ film and a Dy₂O₃ film.

12. The manufacturing method of a semiconductor device according to claim 8, wherein the film containing the second metal is any one of an Al film and an Al₂O₃ film.

13. The manufacturing method of a semiconductor device according to claim 8, further comprising forming a film made of a third metal in the N-channel MOSFET forming region and the P-channel MOSFET formation region, after removing the film containing the second metal and before forming the first high-dielectric-constant film and the second high-dielectric-constant film by applying heat treatment to the semiconductor substrate.

14. The manufacturing method of a semiconductor device according to claim 13, wherein the third metal contains at least one metal selected from the group consisting of TiN, WN, TaSiN, TiAlN, Ti, W, TiAl and Ru.

15. The manufacturing method of a semiconductor device according to claim 8, wherein removing the film containing the second metal from the N-channel MOSFET formation region includes an etching process using a chemical solution selected from the group consisting of HF/H₂O, HF/H₂O₂/H₂O and TMAH/H₂O.

16. The manufacturing method of a semiconductor device according to claim 8, wherein removing the film containing the first metal from the P-channel MOSFET formation region includes an etching process using a chemical solution selected from a group consisting of HCl/H₂O, H₂O, H₂O₂/H₂O, O₃/H₂O and HF/H₂O₂.
